(19) United States
(12) Patent Application Publication
(10) Pub. No.: US 2026/0029481 A1
(43) Pub. Date: Jan. 29, 2026

(54) REDUCING A RATE OF CAPACITY LOSS OF A RECHARGEABLE BATTERY

(71) Applicant: Toyota Research Institute, Inc., Los Altos, CA (US)

(72) Inventors: Steven Bartholomew Joseph Torrisi, San Mateo, CA (US); Joseph Harold Montoya, Berkeley, CA (US); Amalie Emmy Trewartha, San Francisco, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/781,043

(22) Filed: Jul. 23, 2024

(51) Int. Cl. G01R 31/392; G01R 31/382; H01M 10/42

(52) U.S. Cl. CPC G01R 31/392; G01R 31/382; H01M 10/4285

(57) ABSTRACT

A system for reducing a rate of capacity loss of a rechargeable battery can include a switch and a controller. The controller can be configured to produce, at a frequency and during a normal operation of the rechargeable battery to provide electrical power to a power-consuming device, a sequence of pulses. A pulse, of the sequence of pulses, can have a duty cycle that defines: (1) a first portion of the pulse during which the switch is positioned to connect the power-consuming device to the rechargeable battery and (2) a second portion of the pulse during which the switch is positioned to connect the power-consuming device to a secondary electrical power source. For example, interrupting a discharge of the rechargeable battery (e.g., during a normal operation of the rechargeable battery to provide electrical power to the power-consuming device) can reduce a rate of degradation of the rechargeable battery.

### TECHNICAL FIELD

The disclosed technologies are directed to reducing a rate of capacity loss of a rechargeable battery.

### BACKGROUND

Including wireless technologies in devices configured to perform communications operations can increase a degree of portability of such devices. Additionally, the development of rechargeable battery technologies can further enhance the degree of portability of such devices. Such devices can typically be configured so that rechargeable batteries can be contained within housings of the devices. Accordingly, replacement of such rechargeable batteries can be difficult and there exists a desire to extend, to an extent practical, operable lives of rechargeable batteries. For example, a measure of an operable life of a rechargeable battery can be a cycle life of the rechargeable battery, a count of the number of times that a rechargeable battery can be recharged before a capacity of the rechargeable battery decreases. Additionally, other measures of a “state of health” of a rechargeable battery can be used.

### SUMMARY

In an embodiment, a system for reducing a rate of capacity loss of a rechargeable battery can include a switch and a controller. The controller can be configured to produce, at a frequency and during a normal operation of the rechargeable battery to provide electrical power to a power-consuming device, a sequence of pulses. A pulse, of the sequence of pulses, can have a duty cycle that defines: (1) a first portion of the pulse during which the switch is positioned to connect the power-consuming device to the rechargeable battery and (2) a second portion of the pulse during which the switch is positioned to connect the power-consuming device to a secondary electrical power source.

In another embodiment, a system for reducing a rate of capacity loss of a rechargeable battery can include a switch and a controller. The controller can be configured to produce, at a frequency determined from a result of a diagnostic test operation of a rechargeable battery, a sequence of pulses, a pulse, of the sequence of pulses. A pulse, of the sequence of pulses, can have a duty cycle that defines: (1) a first portion of the pulse during which the switch is positioned to connect a power-consuming device to the rechargeable battery and (2) a second portion of the pulse during which the switch is positioned to connect the power-consuming device to a secondary electrical power source.

In another embodiment, a system for reducing a rate of capacity loss of a rechargeable battery can include a switch and a controller. The controller can be configured to produce, at a frequency determined by a machine learning model, a sequence of pulses. A pulse, of the sequence of pulses, can have a duty cycle that defines: (1) a first portion of the pulse during which the switch is positioned to connect a power-consuming device to a rechargeable battery and (2) a second portion of the pulse during which the switch is positioned to connect the power-consuming device to a secondary electrical power source.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 is a block diagram that illustrates an example of a system for reducing a rate of capacity loss of a rechargeable battery, according to the disclosed technologies.

FIG. 2 is a graph that illustrates an example of a sequence of pulses, according to the disclosed technologies.

FIG. 3 are graphs that illustrate examples of values of current through the rechargeable battery and a secondary electrical power source, according to the disclosed technologies.

FIG. 4 includes a block diagram that illustrates an example of elements disposed on a vehicle, according to the disclosed technologies.

### DETAILED DESCRIPTION

The disclosed technologies are directed to reducing a rate of capacity loss of a rechargeable battery. An ability of a rechargeable battery to have a long operable life can depend, for example, upon an ability to reduce a rate of degradation of the rechargeable battery. Degradation of a rechargeable battery can result, for example, in capacity loss, a phenomenon in which an amount of charge that a rechargeable battery can produce at a rated voltage can decrease as a count of the number of times that the rechargeable battery is used increases. Degradation of a rechargeable battery can be caused, for example, by stresses imposed on the rechargeable battery. Such stresses can be produced, for example, by one or more of operating a rechargeable battery at a temperature different from a rated temperature, a rate of charge (or discharge) of a rechargeable battery, changes in a state of charge of a rechargeable battery, electrolyte degradation, mechanical degradation (e.g., formation of cracks within components of a rechargeable battery, expansion and compression of particles within a rechargeable battery, etc.), formation of dendrites within a rechargeable battery, or the like.

The inventors have reasons to believe that interrupting, at a frequency, a discharge of a rechargeable battery (e.g., during a normal operation of the rechargeable battery to provide electrical power to a power-consuming device) can reduce a rate of degradation of the rechargeable battery, which can extend an operable life of the rechargeable battery. Such an interrupting technique can be more effective in a situation in which a power-consuming device, to which the electrical power of the rechargeable battery is provided, is such that the discharge of the rechargeable battery occurs at a constant rate over a long duration of time (e.g., a cell phone) rather than in a situation in which the power-consuming device, to which the electrical power of the rechargeable battery is provided, is such that the discharge of the rechargeable battery is naturally and frequently interrupted (e.g., an electric vehicle with regenerative braking operating in an urban environment).

The disclosed technologies can include a system for reducing a rate of capacity loss of a rechargeable battery. The system can include a switch and a controller. The controller can be configured to produce, at a frequency and during a normal operation of the rechargeable battery to provide electrical power to a power-consuming device, a sequence of pulses. A pulse, of the sequence of pulses, can have a duty cycle that defines a first portion of the pulse and a second portion of the pulse. During the first portion of the pulse, the switch can be positioned to connect the power-consuming device to the rechargeable battery. During the second portion of the pulse, the switch can be positioned to connect the power-consuming device to a secondary electrical power source. For example, a value of the frequency of the sequence of pulses can be based on a cause of degradation of the rechargeable battery. For example, the cause of degradation of the rechargeable battery can include one or more of operating the rechargeable battery at a temperature different from a rated temperature, a rate of charge of the rechargeable battery, a rate of discharge of the rechargeable battery, changes in a state of charge of the rechargeable battery, electrolyte degradation, mechanical degradation, or a formation of a dendrite within the rechargeable battery.

For example, a rated current of the secondary electrical power source can be equal to a rated current of the rechargeable battery. For example, a duration of time of the second portion of the pulse can be no longer than a duration of time necessary to allow both: (1) a value of a current through the rechargeable battery to be decreased, after the switch has been disconnected from the rechargeable battery, to zero and (2) a value of a current through the secondary electrical power source to be increased, after the switch has been connected to the secondary electrical power source, to the rated current of the secondary electrical power source. That is, the duration of time of the second portion of the pulse can be long enough just to interrupt, at the frequency of the sequence of pulses, having electrical power provided to the power-consuming device from the rechargeable battery. During such an interruption, electrical power can continue to be provided to the power-consuming device by the secondary electrical power source.

For example, if a maximum rate of a formation of a dendrite within the rechargeable battery occurs two seconds after a commencement of the normal operation of the rechargeable battery to provide electrical power to the power-consuming device, then by having a value of the frequency of the sequence of pulses being set to one second, the formation of the dendrite can be disrupted before the formation is at the maximum rate. This can reduce a rate of degradation of the rechargeable battery, which can extend an operable life of the rechargeable battery.

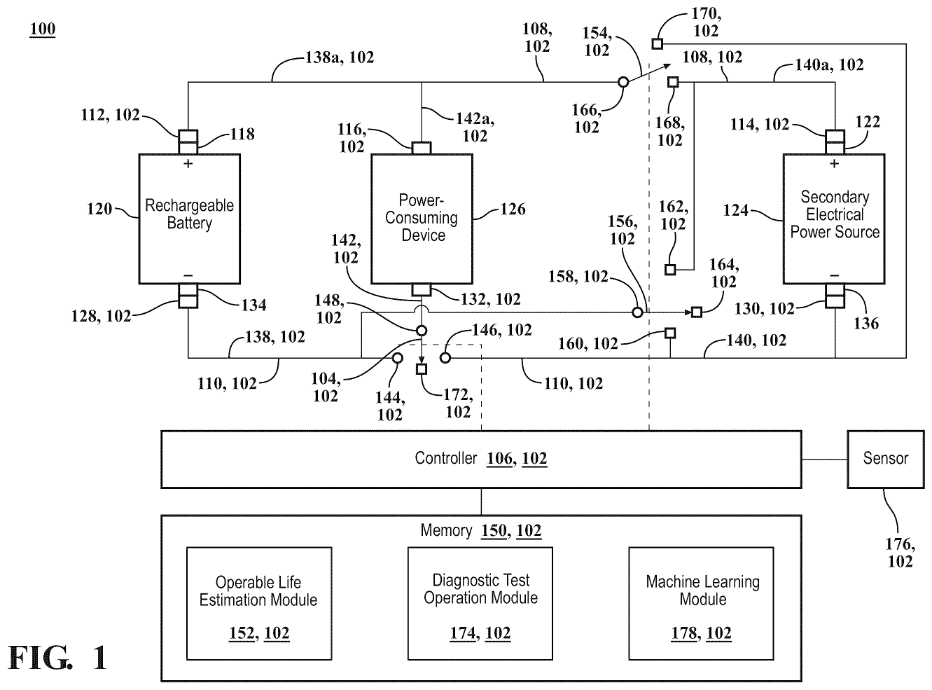

FIG. 1 is a block diagram 100 that illustrates an example of a system 102 for reducing a rate of capacity loss of a first rechargeable battery, according to the disclosed technologies. The system 102 can include, for example, a first switch 104 and a controller 106.

For example, the system 102 can include a first set of conductive structures 108 and a second set of conductive structures 110. For example, the first set of conductive structures 108 can include a first contact 112, a second contact 114, and a first lead 116. For example, the first contact 112 can be configured to be connected to a cathode terminal 118 of a first rechargeable battery 120. For example, the second contact 114 can be configured to be connected to a cathode terminal 122 of a secondary electrical power source 124. For example, the first lead 116 can be connected to a power-consuming device 126. For example, the second set of conductive structures 110 can include a third contact 128, a fourth contact 130, and a second lead 132. For example, the third contact 128 can be configured to be connected to an anode terminal 134 of the first rechargeable battery 120. For example, the fourth contact 130 can be configured to be connected to an anode terminal 136 of the secondary electrical power source 124. For example, the second lead 132 can be connected to the power-consuming device 126.

For example, the first switch 104 can be disposed among a first conductive structure 138, a second conductive structure 140, and a third conductive structure 142 (illustrated). For example, the first conductive structure 138, the second conductive structure 140, and the third conductive structure 142 can be of the second set of conductive structures 110 in which the first conductive structure 138 can be connected to the third contact 128, the second conductive structure 140 can be connected to the fourth contact 130, and the third conductive structure 142 can be connected to the second lead 132. Alternatively, for example, the first switch 104 can be disposed among a first conductive structure 138a, a second conductive structure 140a, and a third conductive structure 142a (not illustrated). For example, the first conductive structure 138a, the second conductive structure 140a, and the third conductive structure 142a can be of the first set of conductive structures 108 in which the first conductive structure 138a can be connected to the first contact 112, the second conductive structure 140a can be connected to the second contact 114, and the third conductive structure 142a can be connected to the first lead 116.

For example, the first switch 104 can have a fifth contact 144, a sixth contact 146, and a seventh contact 148. For example, the fifth contact 144 can be connected to the first conductive structure 138. For example, the sixth contact 146 can be connected to the second conductive structure 140. For example, the seventh contact 148 can be connected to the third conductive structure 142. For example, the first switch 104 can be configured to connect the seventh contact 148 selectively to the fifth contact 144 (i.e., so that the first rechargeable battery 120 can provide electrical power to the power-consuming device 126) or the sixth contact 146 (i.e., so that the secondary electrical power source 124 can provide electrical power to the power-consuming device 126).

For example, the controller 106 can be configured to produce, at a frequency and during a normal operation of the first rechargeable battery 120 to provide electrical power to the power-consuming device 126, a sequence of pulses. A pulse, of the sequence of pulses, can have a duty cycle that defines a first portion of the pulse and a second portion of the pulse.

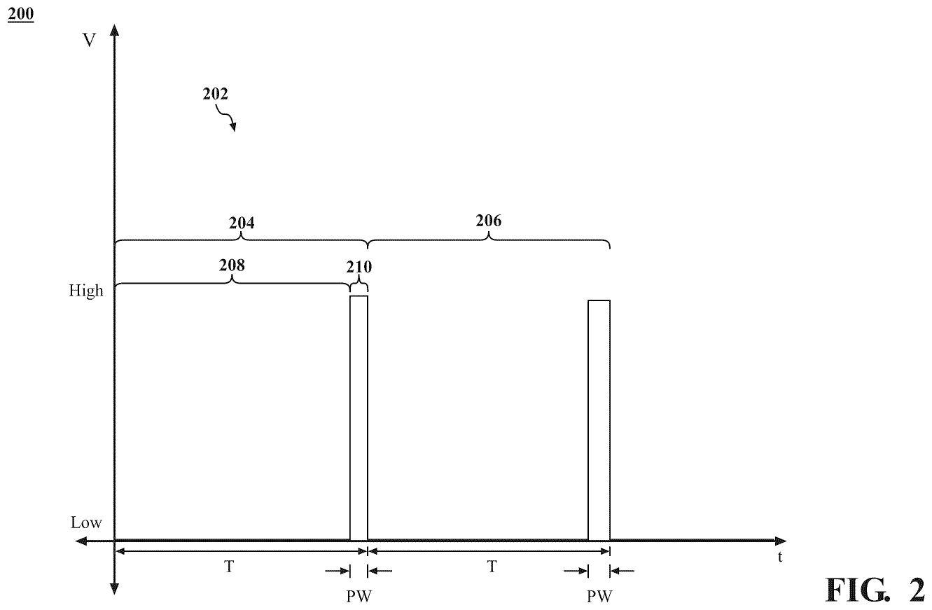

FIG. 2 is a graph 200 that illustrates an example of a sequence of pulses 202, according to the disclosed technologies. The graph 200 can be a function of voltage (V) versus time (t). For example, the sequence of pulses 202 can include a first pulse 204 and a second pulse 206. Each of the first pulse 204 and the second pulse 206 can be defined by a period (T). For example, the first pulse 204 can have a first portion 208 and a second portion 210. For example, the first portion 208 can be characterized by a low value of voltage and the second portion 210 can be characterized by a high value (illustrated) so that a pulse width (PW) can be defined by the second portion 210, and the duty cycle can be a quotient of the pulse width (PW) divided by the period (T). Alternatively, for example, the first portion 208 can be characterized by the high value of voltage and the second portion 210 can be characterized by the low value (not illustrated) so that the pulse width (PW) can be defined by the first portion 208, and the duty cycle can be equal to the quotient of the pulse width (PW) divided by the period (T).

Returning to FIG. 1, during the first portion of the pulse, the first switch 104 can be positioned to connect the power-consuming device 126 to the first rechargeable battery 120. For example, the first switch 104 can be positioned to connect the seventh contact 148 to the fifth contact 144. During the second portion of the pulse, the first switch 104 can be positioned to connect the power-consuming device 126 to the secondary electrical power source 124. For example, the first switch 104 can be positioned to connect the seventh contact 148 to the sixth contact 146.

Additionally, for example, the controller 106 can be configured to prevent, during the normal operation of the first rechargeable battery 120 to provide electrical power to the power-consuming device 126, the first switch 104 from being positioned to connect the power-consuming device 126 concurrently to both the first rechargeable battery 120 and the secondary electrical power source 124.

For example, the first switch 104 can include one or more of a transistor, a microelectromechanical switch, or the like.

For example, a value of the frequency of the sequence of pulses can be empirically determined. Alternatively or additionally, for example, the value of the frequency of the sequence of pulses can be based on a cause of degradation of the first rechargeable battery 120. For example, the cause of degradation of the first rechargeable battery 120 can include one or more of operating the first rechargeable battery 120 at a temperature different from a rated temperature, a rate of charge of the first rechargeable battery 120, a rate of discharge of the first rechargeable battery 120, changes in a state of charge of the first rechargeable battery 120, electrolyte degradation, mechanical degradation, or a formation of a dendrite within the first rechargeable battery 120. For example, if a maximum rate of a formation of a dendrite within the first rechargeable battery 120 occurs two seconds after a commencement of the normal operation of the first rechargeable battery 120 to provide electrical power to the power-consuming device 126, then by having a value of the frequency of the sequence of pulses being set to one second, the formation of the dendrite can be disrupted before the formation is at the maximum rate. This can reduce a rate of degradation of the first rechargeable battery 120, which can extend an operable life of the first rechargeable battery 120.

For example, the secondary electrical power source 124 can include one or more of another battery, a fuel cell, a capacitor, a supercapacitor, a generator, a solar cell, a kinetic energy converter, or the like.

For example, a rated current of the secondary electrical power source 124 can be equal to a rated current of the first rechargeable battery 120. For example, a duration of time of the second portion of the pulse can be no longer than a duration of time necessary to allow both: (1) a value of a current through the first rechargeable battery 120 to be decreased, after the first switch 104 has been disconnected from the first rechargeable battery 120, to zero and (2) a value of a current through the secondary electrical power source 124 to be increased, after the first switch 120 has been connected to the secondary electrical power source 124, to the rated current of the secondary electrical power source 124. That is, the duration of time of the second portion of the pulse can be long enough just to interrupt, at the frequency of the sequence of pulses, having electrical power provided to the power-consuming device 126 from the first rechargeable battery 120. During such an interruption, electrical power can continue to be provided to the power-consuming device 126 by the secondary electrical power source 124.

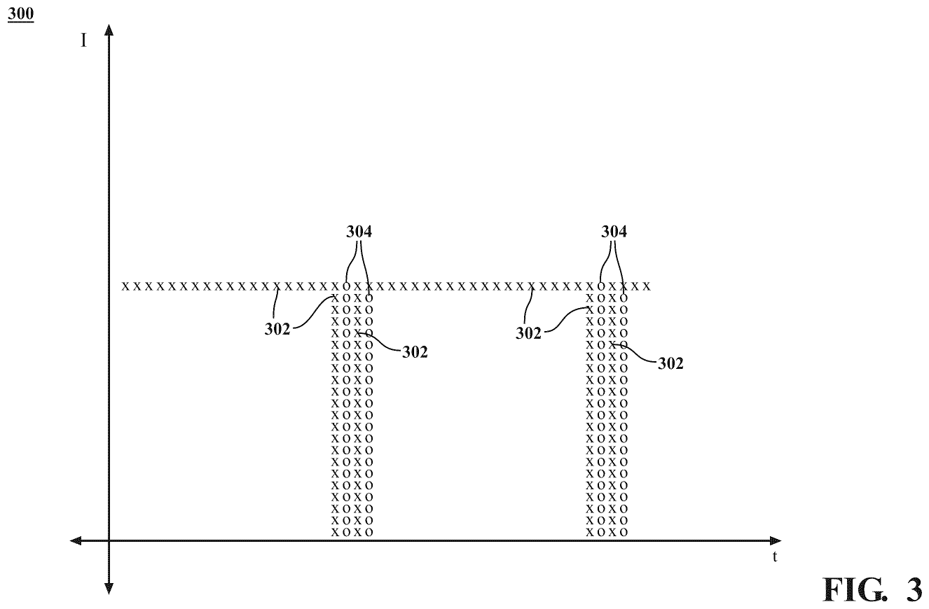

FIG. 3 are graphs 300 that illustrate examples of values of current through the first rechargeable battery 120 and the secondary electrical power source 124, according to the disclosed technologies. The graphs 300 can be a function of current (I) versus time (t). For example, the graphs 300 can include a first graph 302 and a second graph 304. For example, the first graph 302 can be a graph of the current through the first rechargeable battery 120. For example, the second graph 304 can be a graph of the current through the secondary electrical power source 124.

For example, a measurement of a current produced by the secondary electrical power source 124 can be less than a measurement of a current produced by the first rechargeable battery 120. For example, because, as illustrated in FIG. 3, the power-consuming device 126 can consume a greater amount of power from the first rechargeable battery 120 than from the secondary electrical power source 124, the measurement of the current produced by the secondary electrical power source 124 can be less than the measurement of the current produced by the first rechargeable battery 120.

Returning to FIG. 1, alternatively, for example, the secondary electrical power source 124 can be a second rechargeable battery. For example, the second rechargeable battery can be similar to the first rechargeable battery 120. For example, a duration of time of the second portion of the pulse can be equal to a duration of time of the first portion of the pulse.

For example, if the maximum rate of a formation of a dendrite within a rechargeable battery occurs two seconds after the commencement of the normal operation of the first rechargeable battery 120 to provide electrical power to the power-consuming device 126, then by having: (1) the value of the frequency of the sequence of pulses being set to one second and (2) the duration of time of the second portion of the pulse being equal to the duration of time of the first portion of the pulse, the formation of the dendrite can be disrupted, in both the first rechargeable battery 120 and the second rechargeable battery, before the formation is at the maximum rate. This can reduce the rate of degradation of both the first rechargeable battery 120 and the second rechargeable battery, which can extend the operable lives of both the first rechargeable battery 120 and the second rechargeable battery.

Additionally, for example, the system 102 can further include a memory 150. The memory 150 can be communicably coupled to the controller 106. For example, the memory 150 can store an operable life estimation module 152. For example, the operable life estimation module 152 can include instructions that function to control the controller 106 to: (1) estimate an operable life of the first rechargeable battery 120 and (2) delay, until a specific point in an estimate of the operable life, a commencement of a production of the sequence of pulses. For example, degradation of the first rechargeable battery 120 may not be a concern during a phase of the operable life before the specific point.

Additionally, for example, the system 102 can further include the memory 150. The memory 150 can be communicably coupled to the controller 106. For example, the memory 150 can store the operable life estimation module 152. For example, the operable life estimation module 152 can include instructions that function to control the controller 106 to: (1) estimate the operable life of the first rechargeable battery 120, (2) divide an estimate of the operable life into a plurality of phases, and (3) cause a value of the frequency of the sequence of pulses for a first phase, of the plurality of phases, to be a first value, and the value of the frequency of the sequence of pulses for a second phase, of the plurality of phases, to be a second value. For example, the value of the frequency of the sequence of pulses for a later phase of the operable life of the first rechargeable battery 120 may be greater than the value of the frequency of the sequence of pulses for an earlier phase of the operable life of the first rechargeable battery 120.

Additionally, for example, the system 102 can further include a second switch 154, a third switch 156, and the memory 150.

For example, one or more of the second switch 154 or the third switch 156 can include one or more of a transistor, a microelectromechanical switch, or the like.

For example, the second switch 154 can be disposed among the first conductive structure 138a, the second conductive structure 140a, and the second conductive structure 140. For example, the second switch 154 can have an eighth contact 158, a ninth contact 160, a tenth contact 162, and an eleventh contact 164. For example, the eighth contact 158 can be connected to the first conductive structure 138. For example, the ninth contact 160 can be connected to the second conductive structure 140. For example, the tenth contact 162 can be connected to the second conductive structure 140a. For example, the tenth contact 162 can be unconnected to any other conductive structures.

For example, when the system 102 is performing a normal operation to provide electrical power to the power-consuming device 126, the eighth contact 158 can be connected to the tenth contact 162.

For example, the third switch 156 can be disposed among the first conductive structure 138, the second conductive structure 140, and the second conductive structure 140a. For example, the third switch 156 can have a twelfth contact 166, a thirteenth contact 168, and a fourteenth contact 170. For example, the twelfth contact 166 can be connected to the first conductive structure 138a. For example, the thirteenth contact 168 can be connected to the second conductive structure 140a. For example, the fourteenth contact 170 can be connected to the second conductive structure 140.

For example, the second switch 154 and the third switch 156 can allow the system 102 to be configured to perform one or more diagnostic test operations on the first rechargeable battery 120 with electrical power for a diagnostic test operation provided by the secondary electrical power source 124.

For example, the first switch 104 can further have a fifteenth contact 172. For example, the fifteenth contact 172 can be unconnected to any other conductive structures.

For example, when the system 102 is performing a diagnostic test operation, the seventh contact 148, of the first switch 104, can be connected to the fifteenth contact 172.

The memory 150 can be communicably coupled to the controller 106. For example, the memory 150 can store a diagnostic test operation module 174. For example, the diagnostic test operation module 174 can include instructions that function to control the controller 106 to control a performance of a diagnostic test operation of the first rechargeable battery 120 and to control positions of the second switch 154 and the third switch 156.

For example, the diagnostic test operation can include one or more of a hybrid pulse power characterization cycle, a reference performance test, or the like.

For example, during a charging phase of the diagnostic test operation: (1) a position of the second switch 154 can be to connect a cathode of the first rechargeable battery 120 to a cathode of the secondary electrical power source 124 (e.g., the twelfth contact 166 connected to the thirteenth contact 168) and (2) a position of the third switch 156 can be to connect an anode of the first rechargeable battery 120 to an anode of the secondary electrical power source 124 (e.g., the eighth contact 158 connected to the ninth contact 160).

For example, during a discharging phase of the diagnostic test operation: (1) the position of the second switch 154 can be to connect the cathode of the first rechargeable battery 120 to the anode of the secondary electrical power source 124 (e.g., the twelfth contact 166 connected to the fourteenth contact 170) and (2) the position of the third switch 156 can be to connect the anode of the first rechargeable battery 120 to the cathode of the secondary electrical power source 124 (e.g., the eighth contact 158 connected to the tenth contact 162).

Additionally, for example, when the system 102 is configured to perform one or more diagnostic test operations on the first rechargeable battery 120, the memory 150 can further store the operable life estimation module 152. For example, the operable life estimation module 152 can include instructions that function to control the controller 106 to cause the controller 106 to one or more of: (1) determine a value of the frequency of the sequence of pulses based on a result of the diagnostic test operation or (2) estimate an operable life of the first rechargeable battery 120 based on the result of the diagnostic test operation.

Additionally, for example, the system 102 can further include a sensor 176. The sensor 176 can be communicably coupled to the controller 106. For example, the sensor 176 can be configured to obtain information indicative of a context of operation of the system 102.

For example, because operating the first rechargeable battery 120 at a temperature different from a rated temperature of the first rechargeable battery 120 can produce stresses that can cause degradation of the first rechargeable battery 120, the sensor 176 can be configured to obtain information indicative of an ambient temperature of the system 102.

For example, if the system 102 and the secondary electrical power source 124 are disposed on an electric vehicle (not illustrated), the first rechargeable battery 120 is an electric vehicle battery, and the power-consuming device 126 includes an electric motor (and other devices) of the electric vehicle, then because the interrupting technique of the disclosed technologies is more effective in a situation in which the power-consuming device 126 is such that the discharge of the first rechargeable battery 120 occurs at a constant rate over a long duration of time rather than in a situation in which the power-consuming device 126 is such that the discharge of the first rechargeable battery 120 is naturally and frequently interrupted, the sensor 176 can be configured to obtain information about a motion of the electric vehicle. For example, such information may distinguish among a motion of the electric vehicle operating in an urban environment, a motion of the electric vehicle operating in a hilly environment, a motion of the electric vehicle operating on a level and open highway, etc.

For example, the instructions to control the performance of the diagnostic test operation of the first rechargeable battery 120 can include instructions to one or more of: (1) select, based on the information obtained from the sensor 176 and from a set of diagnostic test operations, one or more diagnostic test operations to be performed on the first rechargeable battery 120 or (2) determine, based on the information obtained from the sensor 176, a manner in which a diagnostic test operation, selected to be performed on the first rechargeable battery 120, is to be performed on the first rechargeable battery 120.

Additionally, for example, the system 102 can further include the memory 150. The memory 150 can be communicably coupled to the controller 106. For example, the memory 150 can store a machine learning module 178. For example, the machine learning module 178 can include instructions that function to control the controller 106 to train, using one or more of a result of a diagnostic test operation performed on the first rechargeable battery 120 or information indicative of a context of operation of the system 102, a machine learning model to determine one or more of: (1) a value of the frequency of the sequence of pulses or (2) an estimate of an operable life of the first rechargeable battery 120.

Additionally, for example, the system 102 can further include the memory 150. The memory 150 can be communicably coupled to the controller 106. For example, the memory 150 can store the machine learning module 178. For example, the machine learning module 178 can include instructions that function to control the controller 106 to operate the machine learning module, trained using one or more of a result of a diagnostic test operation performed on the first rechargeable battery 120 or information indicative of a context of operation of the system 102, to produce, based on one or more of an estimate of a current point in an operable life of the first rechargeable battery 120 or a current context of operation of the system 102, one or more of: (1) a value of the frequency of the sequence of pulses or (2) an estimate of a remaining operable life of the first rechargeable battery 120.

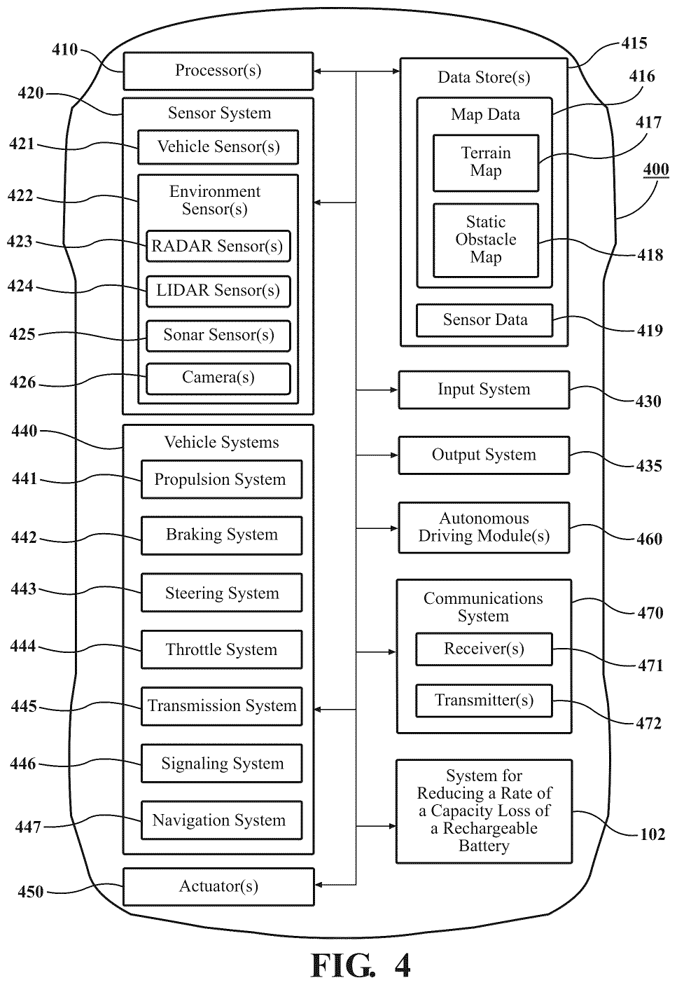

FIG. 4 includes a block diagram that illustrates an example of elements disposed on a vehicle 400, according to the disclosed technologies. As used herein, a “vehicle” can be any form of powered transport. In one or more implementations, the vehicle 400 can be an automobile. While arrangements described herein are with respect to automobiles, one of skill in the art understands, in light of the description herein, that embodiments are not limited to automobiles.

In some embodiments, the vehicle 400 can be configured to switch selectively between an automated mode, one or more semi-automated operational modes, and/or a manual mode. Such switching can be implemented in a suitable manner, now known or later developed. As used herein, “manual mode” can refer that all of or a majority of the navigation and/or maneuvering of the vehicle 400 is performed according to inputs received from a user (e.g., human driver). In one or more arrangements, the vehicle 400 can be a conventional vehicle that is configured to operate in only a manual mode.

In one or more embodiments, the vehicle 400 can be an automated vehicle. As used herein, “automated vehicle” can refer to a vehicle that operates in an automated mode. As used herein, “automated mode” can refer to navigating and/or maneuvering the vehicle 400 along a travel route using one or more computing systems to control the vehicle 400 with minimal or no input from a human driver. In one or more embodiments, the vehicle 400 can be highly automated or completely automated. In one embodiment, the vehicle 400 can be configured with one or more semi-automated operational modes in which one or more computing systems perform a portion of the navigation and/or maneuvering of the vehicle along a travel route, and a vehicle operator (i.e., driver) provides inputs to the vehicle 400 to perform a portion of the navigation and/or maneuvering of the vehicle 400 along a travel route.

For example, Standard J3016 202104, Taxonomy and Definitions for Terms Related to Driving Automation Systems for On-Road Motor Vehicles, issued by the Society of Automotive Engineers (SAE) International on Jan. 16, 2014, and most recently revised on Apr. 30, 2021, defines six levels of driving automation. These six levels include: (1) level 0, no automation, in which all aspects of dynamic driving tasks are performed by a human driver; (2) level 1, driver assistance, in which a driver assistance system, if selected, can execute, using information about the driving environment, either steering or acceleration/deceleration tasks, but all remaining driving dynamic tasks are performed by a human driver; (3) level 2, partial automation, in which one or more driver assistance systems, if selected, can execute, using information about the driving environment, both steering and acceleration/deceleration tasks, but all remaining driving dynamic tasks are performed by a human driver; (4) level 3, conditional automation, in which an automated driving system, if selected, can execute all aspects of dynamic driving tasks with an expectation that a human driver will respond appropriately to a request to intervene; (5) level 4, high automation, in which an automated driving system, if selected, can execute all aspects of dynamic driving tasks even if a human driver does not respond appropriately to a request to intervene; and (6) level 5, full automation, in which an automated driving system can execute all aspects of dynamic driving tasks under all roadway and environmental conditions that can be managed by a human driver.

The vehicle 400 can include various elements. The vehicle 400 can have any combination of the various elements illustrated in FIG. 4. In various embodiments, it may not be necessary for the vehicle 400 to include all of the elements illustrated in FIG. 4. Furthermore, the vehicle 400 can have elements in addition to those illustrated in FIG. 4. While the various elements are illustrated in FIG. 4 as being located within the vehicle 400, one or more of these elements can be located external to the vehicle 400. Furthermore, the elements illustrated may be physically separated by large distances. For example, as described, one or more components of the disclosed system can be implemented within the vehicle 400 while other components of the system can be implemented within a cloud-computing environment, as described below. For example, the elements can include one or more processors 410, one or more data stores 415, a sensor system 420, an input system 430, an output system 435, vehicle systems 440, one or more actuators 450, one or more automated driving modules 460, a communications system 470, and the system 102 for reducing a rate of a capacity loss of a rechargeable battery.

In one or more arrangements, the one or more processors 410 can be a main processor of the vehicle 400. For example, the one or more processors 410 can be an electronic control unit (ECU). For example, functions and/or operations of the controller 106 (illustrated in FIG. 1) can be realized by the one or more processors 410.

The one or more data stores 415 can store, for example, one or more types of data. The one or more data stores 415 can include volatile memory and/or non-volatile memory. Examples of suitable memory for the one or more data stores 415 can include Random-Access Memory (RAM), flash memory, Read-Only Memory (ROM), Programmable Read-Only Memory (PROM), Erasable Programmable Read-Only Memory (EPROM), Electrically Erasable Programmable Read-Only Memory (EEPROM), registers, magnetic disks, optical disks, hard drives, any other suitable storage medium, or any combination thereof. The one or more data stores 415 can be a component of the one or more processors 410. Additionally or alternatively, the one or more data stores 415 can be operatively connected to the one or more processors 410 for use thereby. As used herein, “operatively connected” can include direct or indirect connections, including connections without direct physical contact. As used herein, a statement that a component can be “configured to” perform an operation can be understood to mean that the component requires no structural alterations, but merely needs to be placed into an operational state (e.g., be provided with electrical power, have an underlying operating system running, etc.) in order to perform the operation. For example, functions and/or operations of one or more of the memory 150 (illustrated in FIG. 1) can be realized by the one or more data stores 415.

In one or more arrangements, the one or more data stores 415 can store map data 416. The map data 416 can include maps of one or more geographic areas. In some instances, the map data 416 can include information or data on roads, traffic control devices, road markings, structures, features, and/or landmarks in the one or more geographic areas. The map data 416 can be in any suitable form. In some instances, the map data 416 can include aerial views of an arca. In some instances, the map data 416 can include ground views of an area, including 360-degree ground views. The map data 416 can include measurements, dimensions, distances, and/or information for one or more items included in the map data 416 and/or relative to other items included in the map data 416. The map data 416 can include a digital map with information about road geometry. The map data 416 can be high quality and/or highly detailed.

In one or more arrangements, the map data 416 can include one or more terrain maps 417. The one or more terrain maps 417 can include information about the ground, terrain, roads, surfaces, and/or other features of one or more geographic areas. The one or more terrain maps 417 can include elevation data of the one or more geographic areas. The map data 416 can be high quality and/or highly detailed. The one or more terrain maps 417 can define one or more ground surfaces, which can include paved roads, unpaved roads, land, and other things that define a ground surface.

In one or more arrangements, the map data 416 can include one or more static obstacle maps 418. The one or more static obstacle maps 418 can include information about one or more static obstacles located within one or more geographic areas. A “static obstacle” can be a physical object whose position does not change (or does not substantially change) over a period of time and/or whose size does not change (or does not substantially change) over a period of time. Examples of static obstacles can include trees, buildings, curbs, fences, railings, medians, utility poles, statues, monuments, signs, benches, furniture, mailboxes, large rocks, and hills. The static obstacles can be objects that extend above ground level. The one or more static obstacles included in the one or more static obstacle maps 418 can have location data, size data, dimension data, material data, and/or other data associated with them. The one or more static obstacle maps 418 can include measurements, dimensions, distances, and/or information for one or more static obstacles. The one or more static obstacle maps 418 can be high quality and/or highly detailed. The one or more static obstacle maps 418 can be updated to reflect changes within a mapped area.

In one or more arrangements, the one or more data stores 415 can store sensor data 419. As used herein, “sensor data” can refer to any information about the sensors with which the vehicle 400 can be equipped including the capabilities of and other information about such sensors. The sensor data 419 can relate to one or more sensors of the sensor system 420. For example, in one or more arrangements, the sensor data 419 can include information about one or more lidar sensors 424 of the sensor system 420.

In some arrangements, at least a portion of the map data 416 and/or the sensor data 419 can be located in one or more data stores 415 that are located onboard the vehicle 400. Additionally or alternatively, at least a portion of the map data 416 and/or the sensor data 419 can be located in one or more data stores 415 that are located remotely from the vehicle 400.

The sensor system 420 can include one or more sensors. As used herein, a “sensor” can refer to any device, component, and/or system that can detect and/or sense something. The one or more sensors can be configured to detect and/or sense in real-time. As used herein, the term “real-time” can refer to a level of processing responsiveness that is perceived by a user or system to be sufficiently immediate for a particular process or determination to be made, or that enables the processor to keep pace with some external process.

In arrangements in which the sensor system 420 includes a plurality of sensors, the sensors can work independently from each other. Alternatively, two or more of the sensors can work in combination with each other. In such a case, the two or more sensors can form a sensor network. The sensor system 420 and/or the one or more sensors can be operatively connected to the one or more processors 410, the one or more data stores 415, and/or another element of the vehicle 400 (including any of the elements illustrated in FIG. 4). The sensor system 420 can acquire data of at least a portion of the external environment of the vehicle 400 (e.g., nearby vehicles). The sensor system 420 can include any suitable type of sensor. Various examples of different types of sensors are described herein. However, one of skill in the art understands that the embodiments are not limited to the particular sensors described herein.

The sensor system 420 can include one or more vehicle sensors 421. The one or more vehicle sensors 421 can detect, determine, and/or sense information about the vehicle 400 itself. In one or more arrangements, the one or more vehicle sensors 421 can be configured to detect and/or sense position and orientation changes of the vehicle 400 such as, for example, based on inertial acceleration. In one or more arrangements, the one or more vehicle sensors 421 can include one or more accelerometers, one or more gyroscopes, an inertial measurement unit (IMU), a dead-reckoning system, a global navigation satellite system (GNSS), a global positioning system (GPS), a navigation system 447, and/or other suitable sensors. The one or more vehicle sensors 421 can be configured to detect and/or sense one or more characteristics of the vehicle 400. In one or more arrangements, the one or more vehicle sensors 421 can include a speedometer to determine a current speed of the vehicle 400.

Additionally or alternatively, the sensor system 420 can include one or more environment sensors 422 configured to acquire and/or sense driving environment data. As used herein, “driving environment data” can include data or information about the external environment in which a vehicle is located or one or more portions thereof. For example, the one or more environment sensors 422 can be configured to detect, quantify, and/or sense obstacles in at least a portion of the external environment of the vehicle 400 and/or information/data about such obstacles. Such obstacles may be stationary objects and/or dynamic objects. The one or more environment sensors 422 can be configured to detect, measure, quantify, and/or sense other things in the external environment of the vehicle 400 such as, for example, lane markers, signs, traffic lights, traffic signs, lane lines, crosswalks, curbs proximate the vehicle 400, off-road objects, etc. For example, functions and/or operations of the sensor 176 (illustrated in FIG. 1) can be realized by the one or more environment sensors 422.

Various examples of sensors of the sensor system 420 are described herein. The example sensors may be part of the one or more vehicle sensors 421 and/or the one or more environment sensors 422. However, one of skill in the art understands that the embodiments are not limited to the particular sensors described.

In one or more arrangements, the one or more environment sensors 422 can include one or more radar sensors 423, one or more lidar sensors 424, one or more sonar sensors 425, and/or one more cameras 426. In one or more arrangements, the one or more cameras 426 can be one or more high dynamic range (HDR) cameras or one or more infrared (IR) cameras. For example, the one or more cameras 426 can be used to record a reality of a state of an item of information that can appear in the digital map.

The input system 430 can include any device, component, system, element, arrangement, or groups thereof that enable information/data to be entered into a machine. The input system 430 can receive an input from a vehicle passenger (e.g., a driver or a passenger). The output system 435 can include any device, component, system, element, arrangement, or groups thereof that enable information/data to be presented to a vehicle passenger (e.g., a driver or a passenger).

Various examples of the one or more vehicle systems 440 are illustrated in FIG. 4. However, one of skill in the art understands that the vehicle 400 can include more, fewer, or different vehicle systems. Although particular vehicle systems can be separately defined, each or any of the systems or portions thereof may be otherwise combined or segregated via hardware and/or software within the vehicle 400. For example, the one or more vehicle systems 440 can include a propulsion system 441, a braking system 442, a steering system 443, a throttle system 444, a transmission system 445, a signaling system 446, and/or the navigation system 447. Each of these systems can include one or more devices, components, and/or a combination thereof, now known or later developed. For example, functions and/or operations of the first rechargeable battery 120 (illustrated in FIG. 1) can be realized by the propulsion system 441.

The navigation system 447 can include one or more devices, applications, and/or combinations thereof, now known or later developed, configured to determine the geographic location of the vehicle 400 and/or to determine a travel route for the vehicle 400. The navigation system 447 can include one or more mapping applications to determine a travel route for the vehicle 400. The navigation system 447 can include a global positioning system, a local positioning system, a geolocation system, and/or a combination thereof.

The one or more actuators 450 can be any element or combination of elements operable to modify, adjust, and/or alter one or more of the vehicle systems 440 or components thereof responsive to receiving signals or other inputs from the one or more processors 410 and/or the one or more automated driving modules 460. Any suitable actuator can be used. For example, the one or more actuators 450 can include motors, pneumatic actuators, hydraulic pistons, relays, solenoids, and/or piezoelectric actuators.

The one or more processors 410 and/or the one or more automated driving modules 460 can be operatively connected to communicate with the various vehicle systems 440 and/or individual components thereof. For example, the one or more processors 410 and/or the one or more automated driving modules 460 can be in communication to send and/or receive information from the various vehicle systems 440 to control the movement, speed, maneuvering, heading, direction, etc. of the vehicle 400. The one or more processors 410 and/or the one or more automated driving modules 460 may control some or all of these vehicle systems 440 and, thus, may be partially or fully automated.

The one or more processors 410 and/or the one or more automated driving modules 460 may be operable to control the navigation and/or maneuvering of the vehicle 400 by controlling one or more of the vehicle systems 440 and/or components thereof. For example, when operating in an automated mode, the one or more processors 410 and/or the one or more automated driving modules 460 can control the direction and/or speed of the vehicle 400. The one or more processors 410 and/or the one or more automated driving modules 460 can cause the vehicle 400 to accelerate (e.g., by increasing the supply of fuel provided to the engine), decelerate (e.g., by decreasing the supply of fuel to the engine and/or by applying brakes) and/or change direction (e.g., by turning the front two wheels). As used herein, “cause” or “causing” can mean to make, force, compel, direct, command, instruct, and/or enable an event or action to occur or at least be in a state where such event or action may occur, either in a direct or indirect manner.

The communications system 470 can include one or more receivers 471 and/or one or more transmitters 472. The communications system 470 can receive and transmit one or more messages through one or more wireless communications channels. For example, the one or more wireless communications channels can be in accordance with the Institute of Electrical and Electronics Engineers (IEEE) 802.11p standard to add wireless access in vehicular environments (WAVE) (the basis for Dedicated Short-Range Communications (DSRC)), the 3rd Generation Partnership Project (3GPP) Long-Term Evolution (LTE) Vehicle-to-Everything (V2X) (LTE-V2X) standard (including the LTE Uu interface between a mobile communication device and an Evolved Node B of the Universal Mobile Telecommunications System), the 3GPP fifth generation (5G) New Radio (NR) Vehicle-to-Everything (V2X) standard (including the 5G NR Uu interface), or the like. For example, the communications system 470 can include “connected vehicle” technology. “Connected vehicle” technology can include, for example, devices to exchange communications between a vehicle and other devices in a packet-switched network. Such other devices can include, for example, another vehicle (e.g., “Vehicle to Vehicle” (V2V) technology), roadside infrastructure (e.g., “Vehicle to Infrastructure” (V2I) technology), a cloud platform (e.g., “Vehicle to Cloud” (V2C) technology), a pedestrian (e.g., “Vehicle to Pedestrian” (V2P) technology), or a network (e.g., “Vehicle to Network” (V2N) technology. “Vehicle to Everything” (V2X) technology can integrate aspects of these individual communications technologies.

Moreover, the one or more processors 410, the one or more data stores 415, and the communications system 470 can be configured to one or more of form a micro cloud, participate as a member of a micro cloud, or perform a function of a leader of a micro cloud. A micro cloud can be characterized by a distribution, among members of the micro cloud, of one or more of one or more computing resources or one or more data storage resources in order to collaborate on executing operations. The members can include at least connected vehicles.

The vehicle 400 can include one or more modules, at least some of which are described herein. The modules can be implemented as computer-readable program code that, when executed by the one or more processors 410, implement one or more of the various processes described herein. One or more of the modules can be a component of the one or more processors 410. Additionally or alternatively, one or more of the modules can be executed on and/or distributed among other processing systems to which the one or more processors 410 can be operatively connected. The modules can include instructions (e.g., program logic) executable by the one or more processors 410. Additionally or alternatively, the one or more data store 415 may contain such instructions.

In one or more arrangements, one or more of the modules described herein can include artificial or computational intelligence elements, e.g., neural network, fuzzy logic, or other machine learning algorithms. Further, in one or more arrangements, one or more of the modules can be distributed among a plurality of the modules described herein. In one or more arrangements, two or more of the modules described herein can be combined into a single module.

The vehicle 400 can include one or more automated driving modules 460. The one or more automated driving modules 460 can be configured to receive data from the sensor system 420 and/or any other type of system capable of capturing information relating to the vehicle 400 and/or the external environment of the vehicle 400. In one or more arrangements, the one or more automated driving modules 460 can use such data to generate one or more driving scene models. The one or more automated driving modules 460 can determine position and velocity of the vehicle 400. The one or more automated driving modules 460 can determine the location of obstacles, obstacles, or other environmental features including traffic signs, trees, shrubs, neighboring vehicles, pedestrians, etc.

The one or more automated driving modules 460 can be configured to receive and/or determine location information for obstacles within the external environment of the vehicle 400 for use by the one or more processors 410 and/or one or more of the modules described herein to estimate position and orientation of the vehicle 400, vehicle position in global coordinates based on signals from a plurality of satellites, or any other data and/or signals that could be used to determine the current state of the vehicle 400 or determine the position of the vehicle 400 with respect to its environment for use in either creating a map or determining the position of the vehicle 400 in respect to map data.

The one or more automated driving modules 460 can be configured to determine one or more travel paths, current automated driving maneuvers for the vehicle 400, future automated driving maneuvers and/or modifications to current automated driving maneuvers based on data acquired by the sensor system 420, driving scene models, and/or data from any other suitable source such as determinations from the sensor data 419. As used herein, “driving maneuver” can refer to one or more actions that affect the movement of a vehicle. Examples of driving maneuvers include: accelerating, decelerating, braking, turning, moving in a lateral direction of the vehicle 400, changing travel lanes, merging into a travel lane, and/or reversing, just to name a few possibilities. The one or more automated driving modules 460 can be configured to implement determined driving maneuvers. The one or more automated driving modules 460 can cause, directly or indirectly, such automated driving maneuvers to be implemented. As used herein, “cause” or “causing” means to make, command, instruct, and/or enable an event or action to occur or at least be in a state where such event or action may occur, either in a direct or indirect manner. The one or more automated driving modules 460 can be configured to execute various vehicle functions and/or to transmit data to, receive data from, interact with, and/or control the vehicle 400 or one or more systems thereof (e.g., one or more of vehicle systems 440). For example, functions and/or operations of an automotive navigation system can be realized by the one or more automated driving modules 460.

Detailed embodiments are disclosed herein. However, one of skill in the art understands, in light of the description herein, that the disclosed embodiments are intended only as examples. Therefore, specific structural and functional details disclosed herein are not to be interpreted as limiting, but merely as a basis for the claims and as a representative basis for teaching one of skill in the art to variously employ the aspects herein in virtually any appropriately detailed structure. Furthermore, the terms and phrases used herein are not intended to be limiting but rather to provide an understandable description of possible implementations. Various embodiments are illustrated in FIGS. 1-4, but the embodiments are not limited to the illustrated structure or application.

The flowchart and block diagrams in the figures illustrate the architecture, functionality, and operation of possible implementations of systems, methods, and computer program products according to various embodiments. In this regard, each block in flowcharts or block diagrams may represent a module, segment, or portion of code, which comprises one or more executable instructions for implementing the specified logical function(s). One of skill in the art understands, in light of the description herein, that, in some alternative implementations, the functions described in a block may occur out of the order depicted by the figures. For example, two blocks depicted in succession may, in fact, be executed substantially concurrently, or the blocks may be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suitable. A typical combination of hardware and software can be a processing system with computer-readable program code that, when loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product that comprises all the features enabling the implementation of the methods described herein and that, when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. As used herein, the phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples of the computer-readable storage medium would include, in a non-exhaustive list, the following: a portable computer diskette, a hard disk drive (HDD), a solid-state drive (SSD), a read-only memory (ROM), an erasable programmable read-only memory (EPROM or flash memory), a portable compact disc read-only memory (CD-ROM), a digital versatile disc (DVD), an optical storage device, a magnetic storage device, or any suitable combination of the foregoing. As used herein, a computer-readable storage medium may be any tangible medium that can contain or store a program for use by or in connection with an instruction execution system, apparatus, or device.

Generally, modules, as used herein, include routines, programs, objects, components, data structures, and so on that perform particular tasks or implement particular data types. In further aspects, a memory generally stores such modules. The memory associated with a module may be a buffer or may be cache embedded within a processor, a random-access memory (RAM), a ROM, a flash memory, or another suitable electronic storage medium. In still further aspects, a module as used herein, may be implemented as an application-specific integrated circuit (ASIC), a hardware component of a system on a chip (SoC), a programmable logic array (PLA), or another suitable hardware component (e.g., a central processing unit (CPU), a graphics processing unit (GPU), a field-programmable gate array (FPGA), or the like) that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the disclosed technologies may be written in any combination of one or more programming languages, including an object-oriented programming language such as Java™, Smalltalk, C++, or the like, and conventional procedural programming languages such as the “C” programming language or similar programming languages. The program code may execute entirely on a user's computer, partly on a user's computer, as a stand-alone software package, partly on a user's computer and partly on a remote computer, or entirely on a remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . or . . . ” as used herein refers to and encompasses any and all possible combinations of one or more of the associated listed items. For example, the phrase “at least one of A, B, or C” includes A only, B only, C only, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system, comprising:
a first switch; and
a controller configured to produce, at a frequency and during a normal operation of a first rechargeable battery to provide electrical power to a power-consuming device, a sequence of pulses, a pulse, of the sequence of pulses, having a duty cycle that defines:
a first portion of the pulse during which the first switch is positioned to connect the power-consuming device to the first rechargeable battery; and
a second portion of the pulse during which the first switch is positioned to connect the power-consuming device to a secondary electrical power source.

2. The system of claim 1, wherein the controller is configured to prevent, during the normal operation of the first rechargeable battery to provide electrical power to the power-consuming device, the first switch from being positioned to connect the power-consuming device concurrently to both the first rechargeable battery and the secondary electrical power source.

3. The system of claim 1, wherein a value of the frequency of the sequence of pulses is empirically determined.

4. The system of claim 1, wherein a value of the frequency of the sequence of pulses is based on a cause of degradation of the first rechargeable battery.

5. The system of claim 4, wherein the cause of degradation of the first rechargeable battery comprises at least one of operating the first rechargeable battery at a temperature different from a rated temperature, a rate of charge of the first rechargeable battery, a rate of discharge of the first rechargeable battery, changes in a state of charge of the first rechargeable battery, electrolyte degradation, mechanical degradation, or a formation of a dendrite within the first rechargeable battery.

6. The system of claim 1, wherein the secondary electrical power source comprises at least one of another battery, a fuel cell, a capacitor, a supercapacitor, a generator, a solar cell, or a kinetic energy converter.

7. The system of claim 1, wherein:
a rated current of the secondary electrical power source is equal to a rated current of the first rechargeable battery, and
a duration of time of the second portion of the pulse is no longer than a duration of time necessary to allow both:
a value of a current through the first rechargeable battery to be decreased, after the first switch has been disconnected from the first rechargeable battery, to zero, and
a value of a current through the secondary electrical power source to be increased, after the first switch has been connected to the secondary electrical power source, to the rated current of the secondary electrical power source.

8. The system of claim 1, wherein a measurement of a current produced by the secondary electrical power source is less than a measurement of a current produced by the first rechargeable battery.

9. The system of claim 1, wherein:
the secondary electrical power source is a second rechargeable battery,
the second rechargeable battery is similar to the first rechargeable battery, and
a duration of time of the second portion of the pulse is equal to a duration of time of the first portion of the pulse.

10. The system of claim 1, further comprising a memory storing an operable life estimation module including instructions that, when executed by the controller, cause the controller to:
estimate an operable life of the first rechargeable battery; and
delay, until a specific point in an estimate of the operable life, a commencement of a production of the sequence of pulses.

11. The system of claim 1, further comprising a memory storing an operable life estimation module including instructions that, when executed by the controller, cause the controller to:
estimate an operable life of the first rechargeable battery;
divide an estimate of the operable life into a plurality of phases; and
cause a value of the frequency of the sequence of pulses for a first phase, of the plurality of phases, to be a first value, and the value of the frequency of the sequence of pulses for a second phase, of the plurality of phases, to be a second value.

12. The system of claim 1, further comprising:
a second switch;
a third switch; and
a memory storing a diagnostic test operation module including instructions that, when executed by the controller, cause the controller to control:
a performance of a diagnostic test operation of the first rechargeable battery;
during a charging phase of the diagnostic test operation:
a position of the second switch to connect a cathode of the first rechargeable battery to a cathode of the secondary electrical power source; and
a position of the third switch to connect an anode of the first rechargeable battery to an anode of the secondary electrical power source; and
during a discharging phase of the diagnostic test operation:
the position of the second switch to connect the cathode of the first rechargeable battery to the anode of the secondary electrical power source; and
the position of the third switch to connect the anode of the first rechargeable battery to the cathode of the secondary electrical power source.

13. The system of claim 12, wherein at least one of the first switch, the second switch, or the third switch comprises at least one of a transistor or a microelectromechanical switch.

14. The system of claim 12, wherein the diagnostic test operation comprises at least one of a hybrid pulse power characterization cycle or a reference performance test.

15. The system of claim 12, wherein the memory further stores an operable life estimation module including instructions that, when executed by the controller, cause the controller to at least one of:
determine a value of the frequency of the sequence of pulses based on a result of the diagnostic test operation, or
estimate an operable life of the first rechargeable battery based on the result of the diagnostic test operation.

16. The system of claim 1, further comprising a sensor configured to obtain information indicative of a context of operation of the system.

17. The system of claim 1, further comprising a memory storing a machine learning module including instructions that, when executed by the controller, cause the controller to train, using at least one of a result of a diagnostic test operation performed on the first rechargeable battery or information indicative of a context of operation of the system, a machine learning model to determine at least one of:
a value of the frequency of the sequence of pulses, or
an estimate of an operable life of the first rechargeable battery.

18. The system of claim 1, further comprising a memory storing a machine learning module including instructions that, when executed by the controller, cause the controller to operate a machine learning model, trained using at least one of a result of a diagnostic test operation performed on the first rechargeable battery or information indicative of a context of operation of the system, to produce, based on at least one of an estimate of a current point in an operable life of the first rechargeable battery or a current context of operation of the system, at least one of:
a value of the frequency of the sequence of pulses, or
an estimate of a remaining operable life of the first rechargeable battery.

19. A system, comprising:
a switch; and
a controller configured to produce, at a frequency determined from a result of a diagnostic test operation of a rechargeable battery, a sequence of pulses, a pulse, of the sequence of pulses, having a duty cycle that defines:
a first portion of the pulse during which the switch is positioned to connect a power-consuming device to the rechargeable battery; and
a second portion of the pulse during which the switch is positioned to connect the power-consuming device to a secondary electrical power source.

20. A system, comprising:
a switch; and
a controller configured to produce, at a frequency determined by a machine learning model, a sequence of pulses, a pulse, of the sequence of pulses, having a duty cycle that defines:
a first portion of the pulse during which the switch is positioned to connect a power-consuming device to a rechargeable battery; and
a second portion of the pulse during which the switch is positioned to connect the power-consuming device to a secondary electrical power source.
